(19) United States
(12) Patent Application Publication
(10) Pub. No.: US 2025/0391296 A1
(43) Pub. Date: Dec. 25, 2025

(54) DISPLAY DEVICE AND METHOD OF DRIVING THE SAME, AND ELECTRONIC DEVICE

(71) Applicant: Samsung Display Co., Ltd., Yongin-si (KR)

(72) Inventors: Jung Eon AN, Yongin-si (KR); Ki Hyun PYUN, Yongin-si (KR)

(21) Appl. No.: 19/208,790

(22) Filed: May 15, 2025

(30) Foreign Application Priority Data
Jun. 24, 2024 (KR) 10-2024-0081970

(51) Int. Cl. G09G 3/00; G09G 3/20; G09G 3/3233

(52) U.S. Cl. CPC G09G 3/006; G09G 3/2007; G09G 3/3233; G09G 2300/0819; G09G 2300/0842; G09G 2310/0286; G09G 2320/0233; G09G 2320/0257; G09G 2330/023; G09G 2330/04; G09G 2330/12

(57) ABSTRACT

A display device includes a display having pixels connected to a first power line, a second power line, scanning lines, and data lines; a current sensor to sense a global current value flowing to the pixels; a power generator to supply a first driving power to the first power line, and a second driving power to the second power line; and a timing controller to compare a limit current value corresponding to an upper limit value of a driving current flowing to the pixels with the global current value, and to control the power generator in response to a result of the comparison, and the limit current value is set differently based on image refresh rates of the display.

### CROSS-REFERENCE TO RELATED PATENT APPLICATION

The present application claims priority to and the benefit of Korean Patent Application No. 10-2024-0081970, filed on Jun. 24, 2024, in the Korean Intellectual Property Office, the entire disclosure of which is incorporated herein by reference.

### BACKGROUND

### 1. Field

Embodiments of the present disclosure relate to a display device and a driving method thereof, and an electronic device.

### 2. Description of the Related Art

With the continuing development of information technology, the importance of display devices, which act as an interface between users and information, has been highlighted. As a result, the use of display devices such as liquid crystal display devices and organic light emitting display devices is growing increasing.

Generally, a display device may include pixels. The pixels may display a designated image by emitting light of designated luminance in response to a driving current flowing from a first driving power to a second driving power via a light emitting element.

The display device may set a limit current value (e.g., a set value or threshold that limits the current), and a timing controller may lower a voltage value of the first driving power to prevent the display device from being damaged or to reduce the likelihood that the display device will be damaged if the driving current flowing through the pixels is above the limit current value. Meanwhile, power consumption of the display device may be set differently in response to a driving frequency (or an image refresh rate), and accordingly a method of improving or optimizing the limit current value in response to the driving frequency may be desired or required.

The above information disclosed in this Background section is intended to enhance understanding of the background of the disclosure and may contain information that does not constitute prior art.

### SUMMARY

Aspects of one or more embodiments of the present disclosure are directed to a display device a driving method thereof, and an electronic device including the display device, for improving a display quality by setting different limit current values in response to a driving frequency.

Additional aspects will be set forth in part in the description which follows and, in part, will be apparent from the description, or may be learned by practice of the presented embodiments of the disclosure.

A display device according to one or more embodiments of the present disclosure includes: a display having pixels connected to a first power line, a second power line, scanning lines, and data lines; a current sensor to sense a global current value flowing to the pixels; a power generator to supply a first driving power to the first power line, and a second driving power to the second power line; and a timing controller to compare a limit current value corresponding to an upper limit value of a driving current flowing to the pixels with the global current value, and to control the power generator in response to a result of the comparison, and the limit current value is set differently in response to (e.g., based on) image refresh rates of the display.

According to one or more embodiments, the higher an image refresh rate of the image refresh rates, the lower the limit current value may be set in response to a specific load of the pixels.

According to one or more embodiments, the timing controller may be to control the power generator to lower a voltage of the first driving power if (e.g., when) the global current value is above the limit current value.

According to one or more embodiments, the display device may further include a sensing resistor between the first power line and the display, and the current sensor may be connected to the sensing resistor to sense the global current value.

According to one or more embodiments, the timing controller may include a storage in which a plurality of the limit current values corresponding to image refresh rates are stored, the plurality of limit current values including the limit current value; a frequency determiner to determine a current image refresh rate of the image refresh rates; a selector to select a specific limit current value of the plurality of limit current values corresponding to the current image refresh rate from the storage; and a power controller to control a voltage of the first driving power in response to a comparison result of the global current value and the specific limit current value.

According to one or more embodiments, the frequency determiner may be to receive a vertical synchronization signal, calculate one horizontal period in response to the vertical synchronization signal, and generate a horizontal period signal including information regarding (or on) the one horizontal period.

According to one or more embodiments, the selector may be to select the specific limit current value corresponding to the horizontal period signal and to supply it to the power controller.

According to one or more embodiments, the power controller may be to generate a warning signal if (e.g., when) the global current value is above the specific limit current value.

According to one or more embodiments, the timing controller may further include an analyzer to generate a load and a peak grayscale of input data; and a code value generator to generate a voltage code to control the voltage of the first driving power in response to the load and the peak grayscale and to supply the voltage code to the power generator.

According to one or more embodiments, the code value generator may be to generate the voltage code to lower the voltage of the first driving power if (e.g., when) the warning signal is inputted.

According to one or more embodiments, the code value generator may be to generate the voltage code to lower the voltage of the first driving power in a range for maintaining light-emitting state of the pixels if (e.g., when) the warning signal is inputted.

According to one or more embodiments, the power controller may be to compare the global current value corresponding to the load with the specific limit current value.

A method of driving a display device according to one or more embodiments includes: detecting a global current value corresponding to a driving current flowing to pixels; comparing the global current value with a limit current value corresponding to an upper limit value of the driving current in a power controller; and controlling a voltage of a first driving power which supplies the driving current to the pixels in response to a comparison result of the global current value and the limit current value, and the limit current value is set differently in response to (e.g., based on) image refresh rates of the display.

According to one or more embodiments, the higher an image refresh rate of the image refresh rates, the lower the limit current value may be set in response to a specific load of the pixels.

According to one or more embodiments, the voltage of the first driving power may be lowered if (e.g., when) the global current value is above the limit current value.

According to one or more embodiments, the lowered voltage of the first driving power may be set to allow the pixels to maintain light emission.

According to one or more embodiments, the method may further include calculating one horizontal period using (utilizing) a vertical synchronization signal; determining an image refresh rate of the image refresh rates for driving the display device in response to the one horizontal period; and extracting (selecting) the limit current value corresponding to the image refresh rate and supplying the limit current value to the power controller.

An electronic device according to one or more embodiments includes: a display panel including pixels, where the pixels being are to receive a driving current from a first driving power; a voltage generation circuit to generate the first driving power; and a controller to compare a global current value corresponding to the driving current flowing to the pixels with a limit current value, and to control the voltage generation circuit in response to a comparison result, and the limit current value is set differently for each image refresh rate of the display panel.

According to one or more embodiments, the higher the image refresh rate, the lower the limit current value may be set in response to a specific load of the pixels.

According to one or more embodiments, the controller may be to control the voltage generation circuit to lower a voltage of the first driving power if (e.g., when) the global current value is above the limit current value.

Objects of the present disclosure are not limited to the objects mentioned above, and other technical objects and/or aspects not mentioned may be clearly understood by a person skilled in the art from the following description.

According to a display device and a driving method thereof, and an electronic device according to one or more embodiments of the present disclosure, it is possible to set a limit current value to be high in response to a low image refresh rate, and set the limit current value to be low in response to a high image refresh rate. In such embodiments, it is possible to prevent or reduce the likelihood of a voltage of a first driving power supply from unnecessarily decreasing if (e.g., when) the display device is driven with a low image refresh rate, and thus to improve a display quality. In one or more embodiments, it is possible to prevent or reduce the display device from driving with a high driving current over a designated time if (e.g., when) the display device is driven with a high image refresh rate, and thus to prevent or reduce disorder (or damage) of the pixels.

However, effects of the present disclosure are not limited to the effects described above, and may be modified in one or more suitable ways without departing from the spirit and the scope of the present disclosure.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a diagram illustrating a display device according to one or more embodiments of the present disclosure.

FIG. 2 is a circuit diagram illustrating a pixel of in FIG. 1, according to one or more embodiments of the present disclosure.

FIG. 3A and FIG. 3B are each a graph illustrating the slope of a driving current corresponding to an image refresh rate.

FIG. 4 is a graph illustrating detecting a limit current value corresponding to an image refresh rate.

FIG. 5 is a diagram illustrating a timing controller and a power generator according to one or more embodiments of the present disclosure.

FIG. 6 is a graph illustrating a limit current value stored in a storage of FIG. 5.

FIG. 7 is a graph illustrating power consumption corresponding to a driving frequency.

FIG. 8 is a diagram illustrating an electronic device according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

Further, an expression such as “the same” or “identical” in the description may indicate “substantially the same” or “substantially identical.” For example, the expression may indicate a level of identity enough to establish that the objects, components, layers, etc. are the same and/or identical to those skilled in the art. Even other expressions may also be expressions from which “substantially” is not provided.

Some embodiments are illustrated in relation to functional blocks, units and/or modules in the attached drawings. Those skilled in the art will understand that these blocks, units, and/or modules are physically implemented by a logic circuit, an individual component, a microprocessor, a hardwired circuit, a memory device, wiring connection, and/or other electronic circuit. This may be formed using a semiconductor-based manufacturing technique or other manufacturing technique. A block, a unit and/or a module implemented by a microprocessor or other similar hardware, may be programmed and controlled using software to perform one or more suitable functions discussed in the present disclosure, and may optionally be driven by firmware and/or software. In addition, each block, unit, and/or module may be implemented by dedicated hardware, or may be implemented with a combination of dedicated hardware which performs some function and a processor which performs other function (e.g., one or more programmed microprocessors and associated circuitry). In addition, in some embodiments, the block, the unit, and/or the module may be physically separated into two or more individual blocks, units, and/or modules interacting within a category without departing from the spirit and scope of the present disclosure. Further, in some embodiments, the block, the unit, and/or the module may be combined into physically more complex block, unit, and/or module within a category without departing from the spirit and scope of the present disclosure.

The term “connection” between two components may indicate, but is not necessarily limited to, both an electrical connection and a physical connection. For example, “connection” as used in relation to a circuit diagram may indicate an electrical connection, and “connection” as used in relation to a cross-sectional view and/or a plan view may indicate a physical connection.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to” or “immediately adjacent to” another element or layer, there are no intervening elements or layers present. In addition, it will also be understood that when an element is referred to as being “between” two elements, it can be the only element between the two elements, or one or more intervening elements may also be present.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

As used herein, the terms “use,” “using,” and “used” may be considered synonymous with the terms “utilize,” “utilizing,” and “utilized,” respectively.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

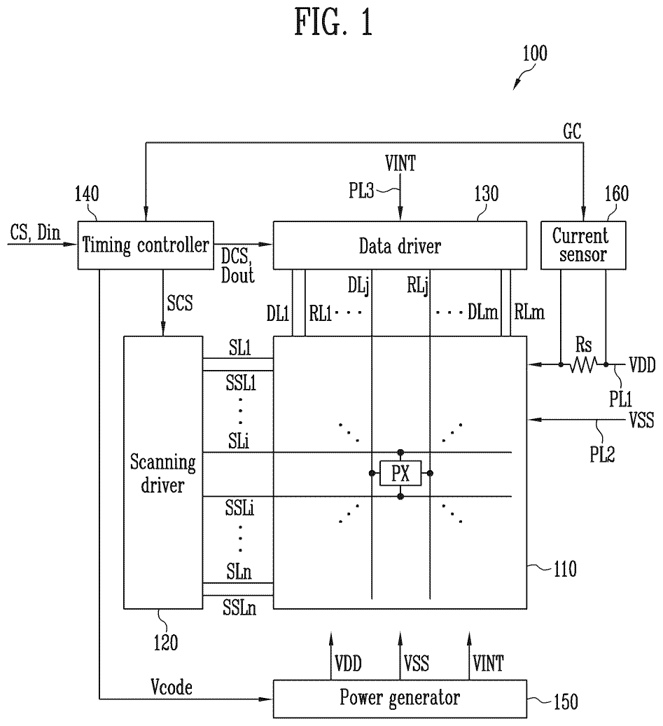

FIG. 1 is a diagram illustrating a display device according to one or more embodiments of the present disclosure.

Referring to FIG. 1, a display device 100 according to one or more embodiments of the present disclosure may include a display 110 (or a display panel), a scanning driver 120, a data driver 130, a timing controller 140, a power generator 150, and a current sensor 160. The scanning driver 120, the data driver 130, the timing controller 140, the power generator 150 and the current sensor 160 may configure (constitute) a driving device which drives the display 110.

The display 110 may display an image. The display 110 may include pixels PX connected to first scanning lines SL1, . . . , SLi, . . . , SLn, second scanning lines SSL1, . . . , SSLi, . . . , SSLn, data lines DL1, . . . , DLj, . . . , DLm, and readout lines RL1, . . . , RLj, . . . , RLm (where n and m are natural numbers greater than or equal to 3, i is a natural number smaller than or equal to n and greater than or equal to 1, and j is a natural number smaller than or equal to m and greater than or equal to 1).

The pixel PX may be connected to one of the first scanning lines SL1 through SLn and one of the data lines DL1 through DLm. In one or more embodiments, the pixel PX may be connected to one of the second scanning lines SSL1 through SSLn and one of the readout lines RL1 through RLm.

For example, a pixel PX positioned in an i-th row and an j-th column may be connected to an i-th first line SLi, an i-th second line SSLi, a j-th data line DLj, and a j-th readout line RLj. In one or more embodiments, the pixel PX may be connected to the first power line PL1 to which a first driving power VDD is applied and the second power line PL2 to which a second driving power VSS is applied.

The first driving power VDD is a power which supplies the driving current to the pixel PX, and the second driving power VSS may be a power which receives the driving current from the pixel PX. During a light-emitting period of the pixel PX, the first driving power VDD may be set to a higher voltage than the second driving power VSS.

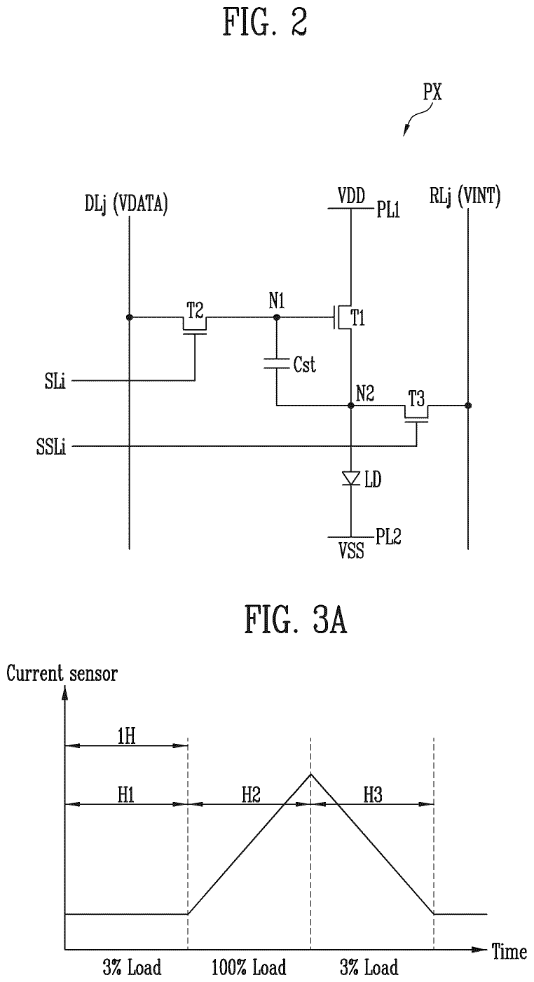

The pixel PX may be initialized by an initialization power VINT provided via the readout line RLj in response to a second scanning signal provided via the second scanning line SSLi, and may receive a data signal VDATA (or data voltage) via the data line DLj in response to a first scanning signal provided through the first scanning line SLi. In response to the data signal VDATA, the pixel PX may generate light of luminance corresponding to the data signal VDATA while controlling the amount of current flowing from the first driving power VDD to the second driving power VSS via a light emitting element LD (see, e.g., FIG. 2). The initialization power VINT may be set to a voltage lower than an operating point (or a threshold voltage) of the light emitting element LD.

The scanning driver 120 may generate a first scanning signal and a second scanning signal based on a scanning control signal SCS. The first scanning signal may be supplied to the first scanning lines SL1 through SLn in sequence, and the second scanning signal may be supplied to the second scanning lines SSL1 through SSLn in sequence.

The scanning control signal SCS may include a start signal and a clock signal, and may be provided from the timing controller 140 to the scanning driver 120. The scanning driver 120 may be implemented as a shift register which sequentially shifts the starting signal in response to the clock signal to sequentially generate and output the first scanning signal in the form of a pulse. In one or more embodiments, the scanning driver 120 may generate and output the second scanning signal in a similar manner of generating the first scanning signal. The scanning driver 120 may include a first scanning driver for generating the first scanning signal and a second scanning driver for generating the second scanning signal.

The scanning driver 120 may be formed together with the pixel PX on the display 110. However, the present disclosure is not limited thereto, and, for example, the scanning driver 120 may be mounted on a circuit film and connected to the timing controller 140 via at least one circuit film and a printed circuit board.

The data driver 130 may generate a data signal VDATA (or data voltage) based on output data Dout and a data control signal DCS provided from the timing controller 140, and provide the data signal VDATA to the display 110 (or the pixel PX) via the data lines DL1 through DLm. Herein, the data control signal DCS may include a data enable signal, a data clock signal, and/or the like. The data driver 130 may provide the initialization power VINT to the display 110 (or the pixel PX) via the readout lines RL1 through RLm.

In one or more embodiments, the data driver 130 may receive a sensing signal through the readout line RL1 through RLm in a separate sensing period (e.g., in a sensing period allocated to sense characteristic information of the pixel PX such as threshold voltage and/or mobility of a driving transistor included in the pixel PX). The sensing signal may be used to compensate for characteristics (or a characteristic deviation) of the pixel PX in the data driver 130 and/or the timing controller 140.

In one or more embodiments, the readout lines RL1 through RLm may be connected to a separate sensor. In this case, the sensor may supply the voltage of the initialization power VINT to the display 110, or receive the sensing signal through the readout line RL1 through RLm.

The power generator 150 may supply the first driving power VDD and the second driving power VSS to the display 110. The power generator 150 may supply the initialization power VINT to the data driver 130.

The power generator 150 may generate the first driving power VDD with a designated voltage in response to a voltage code Vcode supplied from the timing controller 140. The voltage of the first driving power VDD may be determined in response to the voltage code Vcode.

The power generator 150 may provide a driving voltage for driving at least one of the scanning driver 120, the data driver 130, the timing controller 140, and/or the current sensor 160. The power generator 150 may be implemented as a power management integrated circuit (PMIC).

The first driving power VDD may be supplied to the display 110 through the first power line PL1. The second driving power VSS may be supplied to the display 110 through the second power line PL2. The initialization power VINT may be supplied to the data driver 130 via the third power line PL3. The first power line PL1 and the second power line PL2 may be connected to pixels PX in common.

A sensing resistor Rs may be connected to the first power line PL1 which is commonly connected to the pixels PX. For example, the sensing resistor Rs may be connected between the first power line PL1 and the display 110. In this case, the voltage (and the current) of the first driving power VDD may be supplied to the display 110 via the sensing resistor Rs.

The current sensor 160 may be electrically connected to both ends of the sensing resistor Rs. The current sensor 160 may sense the current flowing through the sensing resistor Rs, and thus generate a global current value GC. The global current value GC generated (or sensed) at the current sensor 160 may be provided to the timing controller 140.

The global current value GC may correspond to the current commonly supplied to the pixels PXs via the first power line PL1. However, the present disclosure is not limited thereto, and, for example, the sensing resistor Rs may be connected to the second power line PL2 commonly connected to pixels PXs to sense the current flowing through the second power line PL2. In such embodiments, the current sensor 160 may generate the global current value GC from the sensing resistor Rs connected to the second power line PL2.

The timing controller 140 may receive input data Din and a control signal CS from outside (e.g., from a graphics processor, an application processor, and/or the like), and generate the scanning control signal SCS and the data control signal DCS based on the control signal CS.

In one or more embodiments, the timing controller 140 may store different limit current values respectively corresponding to the image refresh rates (or the driving frequencies). Herein, the limit current value may correspond to an upper limit of a preset driving current. For example, if (e.g., when) the driving current flowing in the display 110 is set above the limit current value, disorder (or damage) may occur in the pixels PX.

The timing controller 140 may receive the global current value GC from the current sensor 160, and determine whether the global current value GC is greater than or equal to the limit current value (or a current limit current value) corresponding to a current image refresh rate. For example, if (e.g., when) the global current value GC is above the current limit current value, the timing controller 140 may generate a voltage code Vcode to lower the voltage of the first driving power VDD.

When the global current value GC is above the current limit current value, the power generator 150 may lower the voltage of the first driving power VDD in response to control of the timing controller 140. Then, the driving current flowing to the pixels PX is reduced, thus preventing or reducing the likelihood of disorder in the pixels PX.

Additionally, the power generator 150 may lower the voltage of the first driving power VDD to maintain light emission in the pixels PX. For example, if a normal voltage of the first driving power VDD is 22 V, and the voltage of the first driving power VDD for maintaining the light emission of the pixels PX is 12 V, the power generator 150 may lower the voltage of the first driving power VDD to a voltage lower than 22 V and higher than 12 V in response to the voltage code Vcode. For example, in one or more embodiments of the present disclosure, the pixels PXs may maintain the light emission even if the global current value GC is above the current limit current value, thus maintaining a minimum display quality.

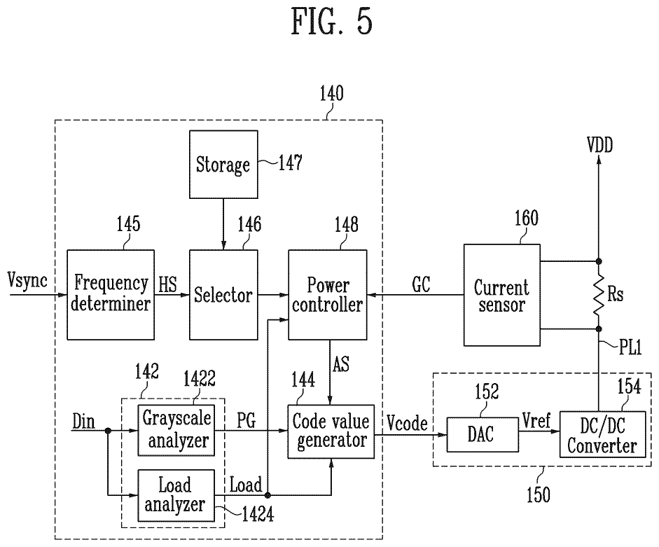

In one or more embodiments, the timing controller 140 may generate the voltage code Vcode by referring to load Load (see, e.g., FIG. 5) and a peak grayscale PG (see, e.g., FIG. 5) of the input data Din, and supply the generated voltage code Vcode to the power generator 150. In such embodiments, the voltage of the first driving power VDD may be changed in response to the load Load and the peak grayscale PG of the input data Din, and accordingly the power consumption of the display device 100 may be reduced.

FIG. 2 is a circuit diagram illustrating a pixel shown in FIG. 1, according to one or more embodiments of the present disclosure. In FIG. 2, the pixel PX positioned in the i-th row and the j-th column is illustrated. The pixel PX shown in FIG. 2 is an example according to one or more embodiments, and the structure of the pixel PX of the present disclosure is not limited thereto. For example, in one or more embodiments of the present disclosure, the pixel PX may be selected from any one of one or more suitable circuits generally available and/or generally utilized.

Referring to FIG. 2, the pixel PX may be connected to the first scanning line SLi, the second scanning line SSLi, the data line DLj and the readout line RLj.

The pixel PX may have a light emitting element LD, a first transistor T1 (or a driving transistor), a second transistor T2, a third transistor T3, and a storage capacitor Cst. The first transistor T1, the second transistor T2, and the third transistor T3 may each be a thin-film transistor including, but not limited to, an oxide semiconductor, and for example, at least some of the first transistor T1, the second transistor T2, and/or the third transistor T3 may include a polysilicon semiconductor, or may be implemented as an N-type kind semiconductor or a P-type kind semiconductor.

A first electrode (or an anode electrode) of the light emitting element LD may be connected to the first power line PL1 via a second node N2 and the first transistor T1, and a second electrode (or a cathode electrode) may be connected to the second power line PL2. The light emitting element LD may be to emit light of luminance corresponding to the driving current supplied from the first transistor T1.

The light emitting element LD selected may be an organic light emitting diode. In one or more embodiments, the light emitting element LD selected may be an inorganic light emitting diode such as a micro-light emitting diode LED or a quantum dot light emitting diode. In one or more embodiments, the light emitting element LD may be an element configured with an organic material and an inorganic material in combination. FIG. 2 shows that the pixel PX includes a single light emitting element LD, but, in one or more embodiments, the pixel PX may include a plurality of light emitting elements, and the plurality of light emitting elements may be connected mutually in series, in parallel, or in series and parallel.

A first electrode (e.g., a drain electrode) of the first transistor T1 may be connected to the first power line PL1 to which the first driving power VDD is applied, and a second electrode (e.g., a source electrode) may be connected to the second node N2. A gate electrode of the first transistor T1 may be connected to the first node N1. The first transistor T1 may control the amount of current flowing to the light emitting element LD in response to the voltage of the first node N1 (or a gate-source voltage between the gate electrode and the second electrode of the first transistor T1).

A first electrode of the second transistor T2 may be connected to the data line DLj, and a second electrode may be connected to the first node N1. A gate electrode of the second transistor T2 may be connected to the first scanning line SLi. When the first scanning signal is supplied to the first scanning line SLi, the second transistor T2 may be turned on to forward a data signal VDATA from the data line DLj to the first node N1.

The storage capacitor Cst may be formed or connected between the first node N1 and the second node N2. The storage capacitor Cst may store the voltage of the first node N1.

The third transistor T3 may be connected between the readout line RLj and the second node N2. A gate electrode of the third transistor T3 may be connected to the second scanning line SSLi. When the second scanning signal is supplied to the second scanning line SSLi, the third transistor T3 may turn on to forward the voltage of the initialization power VINT from the readout line RLj to the second node N2.

In embodiments in which the second transistor T2 and third transistor T3 are concurrently (e.g., simultaneously) turned on in response to the first scanning signal and the second scanning signal, a voltage difference between the data signal VDATA and the initialization power VINT is stored in the storage capacitor Cst. The first transistor T1 may control the amount of the current flowing to the light emitting element LD in response to the voltage difference stored in the storage capacitor Cst.

By contrast, if the third transistor T3 is turned on during the sensing period and the second node N2 and the readout line RLj are connected, the sensing signal may be provided from the pixel PX to the readout line RLj.

FIG. 3A and FIG. 3B are each a graph illustrating the slope of a driving current corresponding to an image refresh rate. In FIG. 3A and FIG. 3B, the Y axis represents the driving current, and the X axis may represent the load of the display 110 corresponding to time elapsing. Further, FIG. 3A and FIG. 3B assume that the display device 100 has a quad high definition (QHD) resolution (2560×1440).

Referring to FIG. 3A, when the display device 100 is driven at a first image refresh rate (e.g., 240 Hz), one horizontal period 1H may be set to 2.9 μs. The load of the display 110 (or the load of the pixels PX) may be set to 3% during a first horizontal period H1, and to 100% during a second horizontal period H2. Then, the driving current supplied to the display 110 may increase at a first slope during the second horizontal period H2. If the load of the display 110 is set to 3% during a third horizontal period H3, the driving current supplied to the display 110 may be lowered to the first slope during the third horizontal period H3. Herein, the driving current supplied to the display 110 may be sensed (or generated) at the current sensor 160 as the global current value GC.

Referring to FIG. 3B, when the display device 100 is driven at a second image refresh rate (e.g., 480 Hz) higher than the first image refresh rate, one horizontal period 1H may be set to 1.45 μs. The load of the display 110 (or the load of the pixels PX) may be set to 3% during a first horizontal period H1a, and to 100% during a second horizontal period H2a. Then, the driving current supplied to the display 110 may rise at a second slope greater (or steeper) than the first slope during the second horizontal period H2a. If the load of the display 110 is set to 3% during a third horizontal period H3a, the driving current supplied to the display 110 may be lowered at the second slope during the third horizontal period H3a. Herein, the driving current supplied to the display 110 may be sensed (or generated) as the global current value GC at the current sensor 160.

As described above, in the case that the image refresh rate of the display device 100 is different, the rising rate (or the slope) of the driving current may be different in response to the load of the display 110. Hence, in the case that the limit current value is set equal regardless of the image refresh rates, an error may occur in detecting the limit current value.

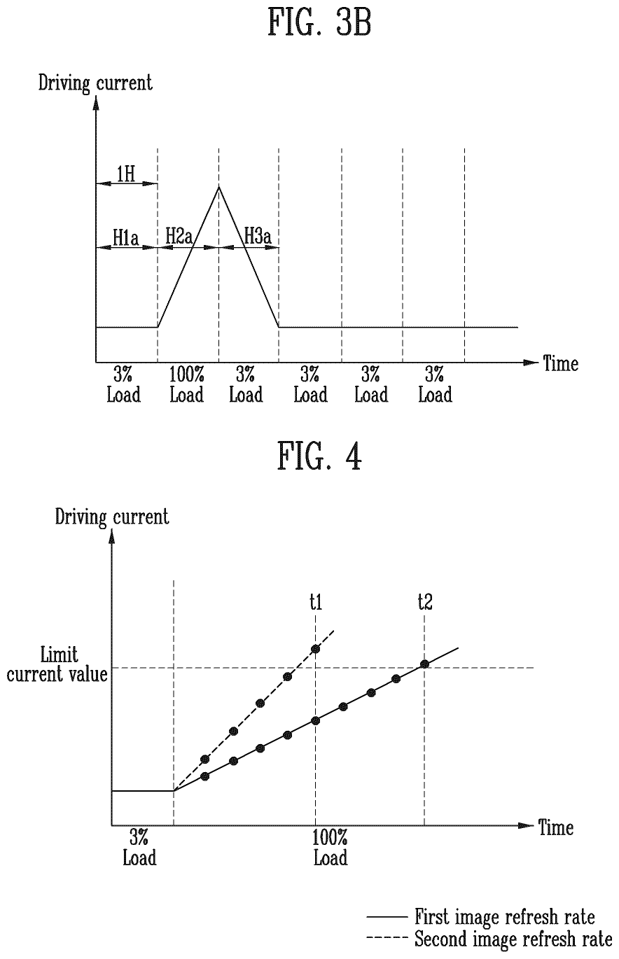

FIG. 4 is a graph illustrating detecting a limit current value corresponding to an image refresh rate.

Referring to FIG. 4, the driving current supplied to the display 110 may be sensed (or generated) as the global current value GC at the current sensor 160. The current sensor 160 may generate the global current value GC at specific intervals and provide it to the timing controller 140. The timing controller 140 may compare the limit current value with the global current value GC at specific intervals, and generate the voltage code Vcode to lower the voltage of the first driving power VDD if the global current value GC is above the limit current value. Herein, the specific interval may be a period shorter than one horizontal period 1H.

In cases in which the display device 100 is driven at the first image refresh rate, the driving current may increase with a first slope which is relatively gentle. In such cases, the driving current rises at the first slope, the current sensor 160 may generate the global current value GC at a second point t2 at which the driving current is above the limit current value. Herein, the global current value GC generated at the second point t2 may be a value similar to the limit current value, thus preventing or reducing the likelihood of the display device 100 driving for a designated time in excess of the limit current value.

In cases in which the display device 100 is driven at the second image refresh rate, the driving current may be raised with a relatively steep second slope. In such cases, the driving current is increased at the second slope, the current sensor 160 may generate the global current value GC at a first point t1 at which the driving current is above the limit current value. The global current value GC generated at the first point t1 is a value exceeding the limit current value by a designated value, and accordingly the display device 100 may be driven for a designated time with the driving current exceeding the limit current value.

As described above, if the limit current value is set equal regardless of the image refresh rates, the display device 100 may be driven at a high image refresh rate by exceeding the limit current value over the designated time.

In addition, the power consumption if (e.g., when) the display device 100 is driven at the first image refresh rate (or a low image refresh rate) may be lower than the power consumption if (e.g., when) the display device 100 is driven at the second image refresh rate (or a high image refresh rate). Thus, if (e.g., when) the display device 100 is driven at the first image refresh rate, a designated driving margin (or power consumption margin), compared to driving at the second image refresh rate, may be attained.

Further, it may be assumed that the limit current value has a constant value regardless of the image refresh rates. For example, the limit current value may be set based on the second image refresh rate to prevent or reduce the likelihood of the display device 100 driving with a high driving current for a designated time.

In such cases, when the display device 100 is driven at the first image refresh rate, the designated driving margin may be attained but the limit current value may be exceeded. For example, when the display device 100 is driven at the first image refresh rate, the voltage of the first driving power VDD may be unnecessarily lowered, and thus the display quality may be degraded.

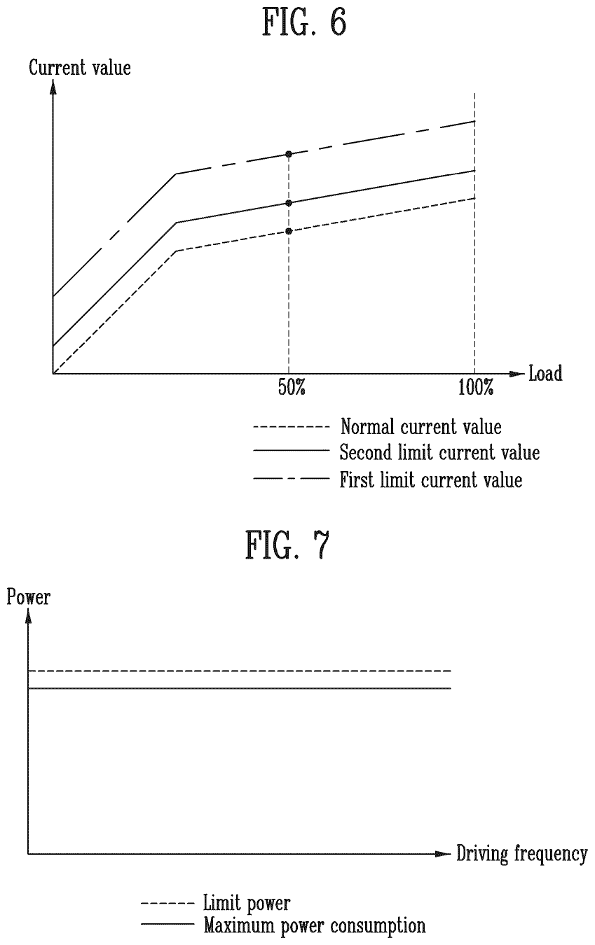

FIG. 5 is a diagram illustrating a timing controller and a power generator according to one or more embodiments of the present disclosure. FIG. 6 is a graph illustrating a limit current value stored in a storage of FIG. 5. In FIG. 6, the Y axis may correspond to the current value, and the X axis may correspond to the load of the display 110.

Referring to FIG. 5, the power generator 150 according to one or more embodiments of the present disclosure may include a digital to analog converter DAC 152 and a direct current DC-DC converter 154.

The DAC 152 may generate a reference voltage Vref (or a feedback voltage) corresponding to the voltage code Vcode, and supply the reference voltage Vref to the DC-DC converter 154. For example, the DAC 152 may supply a reference voltage Vref of between 0 V and 3.3 V (or up to 4.8 V) to the DC-DC converter 154 in response to the voltage code Vcode.

The DC-DC converter 154 may generate the first driving power VDD of a designated voltage based on the reference voltage Vref, and supply the first driving power VDD to the first power line PL1. The voltage of the first driving power VDD generated at the DC-DC converter 154 may be determined based on the voltage of the reference power Vref (i.e., the voltage code Vcode).

The timing controller 140 according to one or more embodiments of the present disclosure may include an analyzer 142, a code value generator 144, a frequency determiner 145, a selector 146, a storage 147 and a power controller 148.

The timing controller 140 may include one or more other suitable components, but FIG. 5 only illustrates only an example of the configuration for the description of the present disclosure.

The analyzer 142 may calculate (or analyze) the load of the input data Din or extract the peak grayscale PG (or a max grayscale). For doing so, the analyzer 142 may include a grayscale analyzer 1422 and/or a load analyzer 1424.

The grayscale analyzer 1422 may extract the peak grayscale PG from the input data Din of one frame. Herein, the peak grayscale PG may indicate the highest grayscale of the input data Din included in one frame.

The load analyzer 1424 may calculate the load of the input data Din corresponding to one frame. For example, the load analyzer 1424 may calculate the load by averaging the grayscale of the input data Din of one frame. A method of calculating the load at the load analyzer 1424 may use one or more suitable methods generally available and/or generally utilized.

The code value generator 144 may generate the voltage code Vcode in response to the peak grayscale PG and the load Load, and supply the generated voltage code Vcode to the power generator 150. Then, the power generator 150 may generate and supply the first driving power VDD corresponding to the peak grayscale PG and the load to the first power line PL1.

A plurality of limit current values may be stored in the storage 147 as shown in FIGS. 5 and 6. In FIG. 6, a normal current value may correspond to current flowing when a general image is displayed on the display 110. The plurality of limit current values (e.g., the first and second limit current values) may have higher current values compared to the normal current value.

A first limit current value may correspond to the first image refresh rate. For example, the first image refresh rate may correspond to the lowest image refresh rate for driving the display device 100.

A second limit current value may correspond to the second image refresh rate. For example, the second image refresh rate may correspond to the highest image refresh rate for driving the display device 100. The second image refresh rate may have a higher driving frequency compared to the first image refresh rate. In response to the same load (e.g., 50%, 100%, and/or the like) of the display 100, the first limit current value may have a higher value compared to the second limit current value. For example, the higher the image refresh rate, the lower the limit current value may be set in response to the same load.

In one or more embodiments of the present disclosure, different limit current values may be set in response to different image refresh rates. The limit current value corresponding to a low image refresh rate may have a higher value at the same load, compared to the limit current value corresponding to a high image refresh rate.

If the first limit current value (or a high limit current value) is set in response to the first image refresh rate (e.g., lower image reference rate), it is possible to prevent or reduce the likelihood of the voltage of the first driving power VDD from being unnecessarily lowered, and thus may prevent or reduce image distortion.

If the second limit current value (or a low limit current value) is set in response to the second image refresh rate (e.g., higher image reference rate), it is possible to prevent or reduce the likelihood of the display device 100 driving with the high driving current for a long time, and thus may prevent or reduce disorder (or damage) of the pixels PX.

In one or more embodiments, the storage 147 may additionally store a plurality of limit current values between the first limit current value and the second limit current value. For example, the storage 147 may store k different limit current values in response to k image refresh rates (where k is a natural number greater than or equal to 3) for driving the display device 100.

The frequency determiner 145 may determine the current image refresh rate (or the current driving frequency). For example, the frequency determiner 145 may receive a vertical synchronization signal Vsync, and calculate one horizontal period 1H in response to the vertical synchronization signal Vsync. The frequency determiner 145 may supply a horizontal period signal HS including information regarding the one horizontal period 1H to the selector 146. The one horizontal period 1H may be set differently in response to (e.g., based on) different image refresh rates (e.g., 1H may be 11.6 μs for 60 Hz, 1H may be 5.8 μs for 120 Hz, 1H may be 2.9 μs for 240 Hz, 1H may be 1.9 μs for 360 Hz, 1H may be 1.45 μs for 480 Hz), and the frequency determiner 145 may determine the current image refresh rate by calculating one horizontal period 1H using the vertical synchronization signal Vsync.

The selector 146 may select the current limit current value from the storage 147 in response to the horizontal period signal HS, and supply the current limit current value to the power controller 148. The current limit current value may be a limit current value corresponding to the image refresh rate for driving the display device 100.

For example, the selector 146 may supply the first limit current value in which the horizontal period signal HS corresponds to the first image refresh rate to the power controller 148 as the current limit current value. For example, the selector 146 may supply a second limit current value in which the horizontal period signal HS corresponds to the second image refresh rate to the power controller 148 as the current limit current value.

The power controller 148 may receive the current limit current value from the selector 146, and receive the global current value GC from the current sensor 160. In one or more embodiments, the power controller 148 may receive a load of a current frame from the load analyzer 1424.

The power controller 148 may compare the global current value GC with the current limit current value, in response to the load of the current frame. For example, if the global current value GC is above the current limit current value, the power controller 148 may supply a warning signal AS (or a warning signal AS of a high voltage) to the code value generator 144. For example, if the global current value GC is below the current limit current value, the power controller 148 may not output the warning signal AS (or it may output a low-voltage warning signal AS).

When the warning signal AS is not inputted, the code value generator 144 may supply the voltage code Vcode corresponding to the peak grayscale PG and the load to the power generator 150. When the warning signal AS is inputted, the code value generator 144 may generate the voltage code Vcode to lower the voltage of the first driving power VDD regardless of the peak grayscale PG and the load. In the case that the voltage of the first driving power VDD is lowered, the driving current supplied to the pixels PX may be reduced, thus preventing or reducing disorder in the pixels PX due to the high driving current.

In one or more embodiments, if the warning signal AS is inputted, the code controller 144 may lower the voltage of the first driving power VDD to maintain the light emission of the pixels PX. For example, even if the warning signal AS is inputted, the pixels PX may maintain the light emission even if it results in the global current value GC being above the current limit current value, and accordingly the display device 100 may secure a minimum display quality.

Additionally, the power controller 148 may supply the warning signal AS to drop the voltage of the first driving power VDD for a period of approximately five frames or less (e.g., a period of two frames or less). The code value generator 144 may generate the voltage code Vcode to lower the voltage of the first driving power VDD for a period of approximately five frames or less. If the voltage of the first driving power VDD is set to a low voltage for the period of approximately five frames or less, the display device 100 may ensure the minimum display quality.

FIG. 7 is a graph illustrating power consumption corresponding to a driving frequency. In FIG. 7, the Y axis represents the power, and the X axis represents the driving frequency. In FIG. 7, limit power may correspond to the highest power consumable by the display device 100.

Referring to FIG. 7, maximum power consumption of the display device 100 may remain approximately constant regardless of the image refresh rate (i.e., the driving frequency). The maximum power consumption may indicate the power consumed if (e.g., when) the display device 100 emits the light with the load of 100%.

In one or more embodiments of the present disclosure, the lower image refresh rate, the higher limit current value is set, and the higher image refresh rate, the lower limit current value is set. If the display device 100 is driven at a low image refresh rate, relatively low power is consumed, and accordingly the limit current value may be set high. If the display device 100 is driven at a high image refresh rate, relatively high power is consumed, and accordingly the limit current value may be set low.

If the limit current value is set differently in response to the image refresh rate, the maximum power consumption of the display device 100 may remain approximately constant in response to the change of the image refresh rate. For example, one or more embodiments of the present disclosure may maintain approximately constant maximum power consumption regardless of the image refresh rate by setting the limit current value differently in response to the image refresh rate.

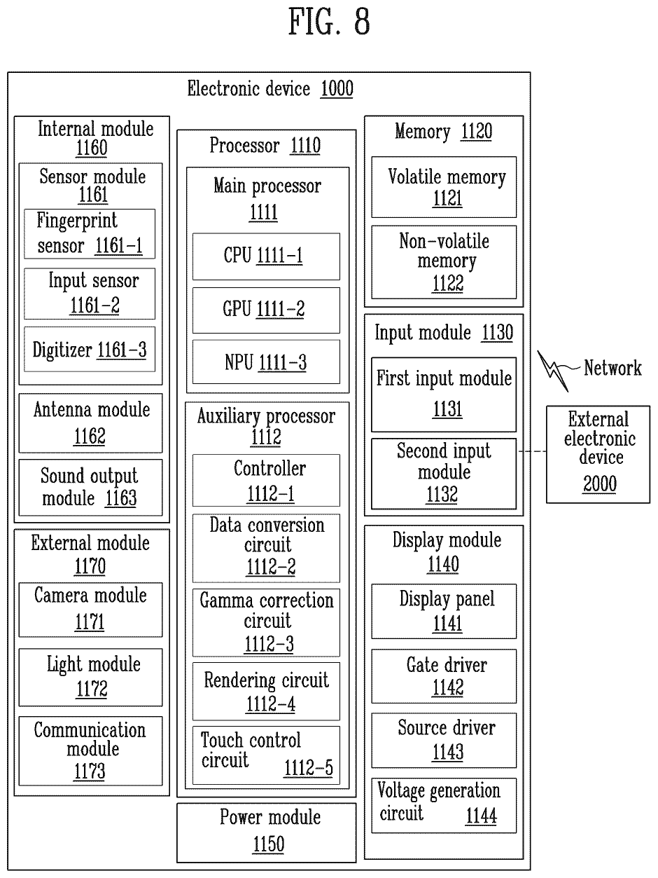

FIG. 8 is a diagram illustrating an electronic device according to one or more embodiments of the present disclosure.

Referring to FIG. 8, an electronic device 1000 according to one or more embodiments of the present disclosure outputs information through a display module 1140. If a processor 1110 executes an application stored in a memory 1120, the display module 1140 provides application information to the user through a display panel 1141.

The processor 1110 obtains an external input through an input module 1130 or a sensor module 1161, and executes an application corresponding to the external input. For example, if the user selects a camera icon (or a camera application icon) displayed on the display panel 1141, the processor 1110 obtains a user input through an input sensor 1161-2 and activates a camera module 1171. The processor 1110 forwards image data corresponding to a captured image acquired through the camera module 1171 to the display module 1140. The display module 1140 may display an image corresponding to the captured image through the display panel 1141.

As another example, if (e.g., when) personal information authentication is conducted in the display module 1140, a fingerprint sensor 1161-1 acquires inputted fingerprint information as input data. The processor 1110 compares the input data acquired through the fingerprint sensor 1161-1 with authentication data stored in the memory 1120, and executes an application according to a comparison result. The display module 1140 may display information executed according to a logic of the application through the display panel 1141. The fingerprint sensor 1161-1 may be arranged to acquire fingerprint information over an entire area of the display module 1140 (or the display panel 1141).

As yet another example, if (e.g., when) a music streaming icon displayed on the display module 1140 is selected, the processor 1110 obtains a user input through the input sensor 1161-2, and activates a music streaming application stored in the memory 1120. When a music execution command is inputted in the music streaming application, the processor 1110 activates a sound output module 1163 to provide the user with sound information corresponding to the music execution command.

As above, the operations of the electronic device 1000 have been described in brief. Hereafter, a configuration of the electronic device 1000 is described in more detail. Some of configurations of the electronic device 1000 to be described may be integrated into a single configuration, or a configuration may be provided separately as two or more configurations.

The electronic device 1000 may communicate with an external electronic device 2000 via a network (e.g., a short-range radio communication network or a long-range radio communication network). According to one or more embodiments, the electronic device 1000 may include the processor 1110, the memory 1120, the input module 1130, the display module 1140, a power module 1150, an internal module 1160, and an external module 1170. According to one or more embodiments, the electronic device 1000 may omit at least one of the above-described components, or one or more other components may be added. According to one or more embodiments, some components (e.g., the sensor module 1161, an antenna module 1162, and/or the sound output module 1163) of the above-described components may be integrated into other component (e.g., the display module 1140).

The processor 1110 may execute software to control at least one other component (e.g., a hardware or software component) of the electronic device 1000 connected to the processor 1110, and perform various (e.g., suitable) data processing or computations. According to one or more embodiments, as at least a part of the data processing or computation, the processor 1110 may store a command or data received from other component (e.g., the input module 1130, the sensor module 1161 or a communication module 1173) in a volatile memory 1121, process a command or data stored in the volatile memory 1121, and store resulting data in a non-volatile memory 1122.

The processor 1110 may include a main processor 1111 and an auxiliary processor 1112. The main processor 1111 may include a central processing unit CPU 1111-1. The main processor 1111 may include one or more of a graphic processing unit GPU 1111-2, a communication processor (CP), and/or an image signal processor (ISP). The main processor 1111 may further include a neural processing unit NPU 1111-3. The NPU 1111-3 is a processor specialized in processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks and/or a (e.g., any suitable) combination of two or more thereof, but is not limited to the aforementioned examples. The artificial intelligence model may, additionally or alternatively, include a software structure other than a hardware structure. At least two of the above-described processing units and processors may be implemented as one integrated configuration (e.g., a single chip), or each may be implemented as an independent configuration (e.g., a plurality of chips).

The auxiliary processor 1112 may include a controller 1112-1. The controller 1112-1 may include an interface conversion circuit and a timing control circuit. For example, the controller 1112-1 may include the timing controller 140 shown in FIG. 1. The controller 1112-1 receives an image signal from the main processor 1111, converts a data format of the image signal to conform to interface specifications with the display module 1140, and outputs the image data. The controller 1112-1 may output one or more suitable control signals for driving the display module 1140.

The controller 1112-1 may compare the global current value GC with the current limit current value, and generate the voltage code Vcode in response to the comparison result. In order to do so, the controller 1112-1 may include the analyzer 142, the code value generator 144, the frequency determiner 145, the selector 146, the storage 147 and the power controller 148 shown in FIG. 5.

The auxiliary processor 1112 may further include a data conversion circuit 1112-2, a gamma correction circuit 1112-3, a rendering circuit 1112-4, and a touch control circuit 1112-5. The data conversion circuit 1112-2 may receive image data from the controller 1112-1, compensate for the image data to display the image with a desired or suitable brightness according to characteristics of the electronic device 1000 or user's setting, or convert the image data for the power consumption reduction or afterimage compensation.

The gamma correction circuit 1112-3 may convert the image data or a gamma reference voltage and/or the like, such that the image displayed on the electronic device 1000 has desired or suitable gamma characteristics. The rendering circuit 1112-4 may receive image data from the controller 1112-1, and render the image data in consideration of pixel arrangement of the display panel 1141 applied to the electronic device 1000.

The touch control circuit 1112-5 may supply a touch signal to the input sensor 1161-2, and receive a sensing signal from the input sensor 1161-2 in response to the touch signal.

At least one of the data conversion circuitry 1112-2, the gamma correction circuit 1112-3, the rendering circuit 1112-4, and/or the touch control circuit 1112-5 may be integrated into another component (e.g., the main processor 1111 or the controller 1112-1). At least one of the data conversion circuit 1112-2, the gamma correction circuit 1112-3, and/or the rendering circuit 1112-4 may be integrated into a source driver 1143 to be described in more detail below.

The memory 1120 may store various (e.g., suitable) data used by at least one component of the electronic device 1000 (e.g., the processor 1110 or the sensor module 1161), and input data or output data for commands related thereto. In one or more embodiments, the memory 1120 may store various (e.g., suitable) configuration data corresponding to user's settings. The memory 1120 may include at least one or more of the volatile memory 1121 and/or the non-volatile memory 1122.

The input module 1130 may receive a command or data to be used in a component of the electronic device 1000 (e.g., the processor 1110, the sensor module 1161 or the sound output module 1163) from outside of the electronic device 1000 (e.g., the user or the external electronic device 2000).

The input module 1130 may include a first input module 1131 for receiving a command or data from the user and a second input module 1132 for receiving a command or data from the external electronic device 2000. The first input module 1131 may include a microphone, a mouse, a keyboard, a key (e.g., a button) or a pen (e.g., a passive pen or an active pen). The second input module 1132 may support a designated protocol for connecting to the external electronic device 2000 by wire or wirelessly. According to one or more embodiments, the second input module 1132 may include a high definition multimedia interface (HDMI), a universal serial bus (USB) interface, a secure digital (SD) card interface, or an audio interface. The second input module 1132 may include a connector for physically connecting to the external electronic device 2000, for example, an HDMI connector, a USB connector, a secure digital (SD) card connector, or an audio connector (e.g., a headphone connector).

The display module 1140 visually provides information to the user. The display module 1140 may include the display panel 1141, a gate driver 1142, a source driver 1143 and a voltage generation circuit 1144. The display module 1140 may further include a window, a chassis, and/or a bracket for protecting the display panel 1141. As such, the display module 1140 may include at least some configuration of the display device 100 shown in FIG. 1.

The display panel 1141 (or the display) may include a liquid crystal display panel, an organic light emitting display panel, or an inorganic light emitting display panel, but the type (or kind) of the display panel 1141 is not particularly limited. The display panel 1141 may be of a rigid type (or kind), or a flexible type (or kind) which may be rolled or folded. The display module 1140 may further include a supporter, a bracket, and/or a heat dissipation member for supporting the display panel 1141. The display panel 1141 may include the display 110 shown in FIG. 1.

The gate driver 1142 may be mounted on the display panel 1141 as a driving chip. In one or more embodiments, the gate driver 1142 may be integrated into the display panel 1141. For example, the gate driver 1142 may include an amorphous silicon thin-film transistor (TFT) gate driver circuit (ASG), a low temperature polycrystalline silicon (LTPS) TFT gate driver circuit, or an oxide semiconductor TFT gate driver circuit (OSG) embedded in the display panel 1141. The gate driver 1142 receives a control signal from the controller 1112-1, and outputs a scanning signal to the display panel 1141 in response to the control signal. The gate driver 1142 may include the scanning driver 120 shown in FIG. 1.

The display module 1140 may further include a light emission driver. The light emission driver outputs a light emission control signal to the display panel 1141 in response to the control signal received from the controller 1112-1. The light emission driver may be formed separately from the gate driver 1142, or may be integrated into the gate driver 1142.

The source driver 1143 receives a control signal from the controller 1112-1, converts image data into an analog voltage (e.g., a data signal, such as data signal VDATA) in response to the control signal, and then outputs data signals to the display panel 1141. The source driver 1143 may include the data driver 130 shown in FIG. 1.

The source driver 1143 may be integrated into other components (e.g., the controller 1112-1). The functions of the interface conversion circuit and the timing control circuit of the controller 1112-1 mentioned above may also be integrated into the source driver 1143. Additionally, the display module 1140 may further include the current sensor 160 shown in FIG. 1.

The voltage generation circuit 1144 may output one or more suitable voltages for driving the display panel 1141. For example, the voltage generation circuit 1144 may include the power generator 150 shown in FIG. 1. The voltage generation circuit 1144 may include the DAC 152 and the DC-DC converter 154 shown in FIG. 5. In one or more embodiments, the display panel 1141 may include the pixels PX shown in FIG. 1.

In one or more embodiments, the source driver 1143 may convert data corresponding to red, green, and blue included in the image data received from the processor 1110 into a red data signal (or data voltage), a green data signal and a blue data signal and provide to a plurality of pixel sequences included in the display panel 1141 for one horizontal period H1.

The power module 1150 supplies power to the components of the electronic device 1000. The power module 1150 may include a battery for charging the power supply voltage. The battery may include a primary cell which is not rechargeable, a secondary cell which is rechargeable, or a fuel cell. The power module 1150 may include a power management integrated circuit (PMIC). The PMIC supplies improved or optimized power to each of the above-mentioned modules and modules to be described. The power module 1150 may include a wireless power transmission and reception member electrically connected to the battery. The wireless power transmission and reception member may include a plurality of antenna radiators in the form of coils. In one or more embodiments, at least some configuration of the power module 1150 and the voltage generation circuit 1144 may be integrated into one. For example, the voltage generation circuit 1144 may be included in the power module 1150.

The electronic device 1000 may further include an internal module 1160 and an external module 1170. The internal module 1160 may include the sensor module 1161, the antenna module 1162, and the sound output module 1163. The external module 1170 may include the camera module 1171, the light module 1172, and the communication module 1173.

The sensor module 1161 may detect an input by a user's body or an input by a pen at the first input module 1131, and generate an electrical signal or a data value corresponding to the input. The sensor module 1161 may include at least one or more of the fingerprint sensor 1161-1, the input sensor 1161-2, and/or a digitizer 1161-3.

The fingerprint sensor 1161-1 may generate a data value corresponding to a user's fingerprint.

The input sensor 1161-2 may generate a data value corresponding to coordinate information of the input by the user's body or the input by a pen. The input sensor 1161-2 generates a capacitance change by the input as a data value. The input sensor 1161-2 may detect the input by a passive pen, or transmit and receive data with an active pen.

The input sensor 1161-2 may measure a bio-signal such as blood pressure, body water, and/or body fat. For example, if the user touches a sensor layer or a sensing panel with a part of the body and does not move for a specific time, the input sensor 1161-2 may detect the bio-signal based on an electric field change due to the body part and output information regarding the bio-signal to the display module 1140.

The digitizer 1161-3 may generate a data value corresponding to the coordinate information of the input by a pen. The digitizer 1161-3 generates an electromagnetic change by the input as the data value. The digitizer 1161-3 may detect the input by a passive pen, or transmit and receive data with an active pen.

At least one of the fingerprint sensor 1161-1, the input sensor 1161-2, and/or the digitizer 1161-3 may be implemented as a sensor layer formed on the display panel 1141 through a substantially continuous process. At least one of the fingerprint sensor 1161-1, the input sensor 1161-2, and/or the digitizer 1161-3 may be arranged on an upper side of the display panel 1141, and any one of the fingerprint sensor 1161-1, the input sensor 1161-2, and/or the digitizer 1161-3, for example, the digitizer 1161-3 may be arranged on a lower side of the display panel 1141.

At least two or more of the fingerprint sensor 1161-1, the input sensor 1161-2, and/or the digitizer 1161-3 may be configured to be integrated into one sensing panel through substantially the same process. When integrated into one sensing panel, the sensing panel may be arranged between the display panel 1141 and a window arranged on an upper side of the display panel 1141. According to one or more embodiments, the sensing panel may be arranged on the window, and the position of the sensing panel is not particularly limited.

At least one of the fingerprint sensor 1161-1, the input sensor 1161-2, and/or the digitizer 1161-3 may be embedded in the display panel 1141. For example, at least one of the fingerprint sensor 1161-1, the input sensor 1161-2, and/or the digitizer 1161-3 may be formed concurrently (e.g., simultaneously) through a process of forming elements (e.g., a light emitting element, a transistor, and/or the like) included in the display panel 1141.

In one or more embodiments, the sensor module 1161 may generate an electrical signal or a data value corresponding to an internal state or an external state of the electronic device 1000. The sensor module 1161 may further include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 1162 may include one or more antennas for transmitting or receiving signals or power to the outside or from the outside. In one or more embodiments, the communication module 1173 may be to transmit or receive a signal to or from an external electronic device via an antenna appropriate or suitable for a communication scheme. An antenna pattern of the antenna module 1162 may be integrated into one configuration (e.g., the display panel 1141) of the display module 1140 or the input sensor 1161-2.

The sound output module 1163 is a device for outputting a sound signal to the outside of the electronic device 1000, and may include, for example, a speaker used for a general purpose such as multimedia playback or recording playback and a receiver used exclusively for call reception. According to one or more embodiments, the receiver may be configured integrally with or separately from the speaker. A sound output pattern of the sound output module 1163 may also be integrated into the display module 1140.

The camera module 1171 may capture a still image and a moving image. According to one or more embodiments, the camera module 1171 may include one or more lenses, an image sensor, or an image signal processor. The camera module 1171 may further include an infrared camera for measuring the presence or absence of the user, a user's location and/or a user's line of sight.

The light module 1172 may provide light. The light module 1172 may include a light emitting diode or a xenon lamp. The light module 1172 may operate in conjunction with the camera module 1171 or may operate independently.

The communication module 1173 may support establishment of a wired or wireless communication channel between the electronic device 1000 and the external electronic device 2000, and communication over the established communication channel. The communication module 1173 may include or any one or all of a wireless communication module such as a cellular communication module, a short-range wireless communication module or a global navigation satellite system (GNSS) communication module, and/or a wired communication module such as a local area network (LAN) communication module or a power line communication module. The communication module 1173 may communicate with the external electronic device 2000 via a short-range communication network such as Bluetooth, wireless-fidelity (Wi-Fi) direct, or infrared data association (IrDA), and/or a long-range communication network such as a cellular network, Internet, or a computer network (e.g., LAN or wide area network (WAN)). The various types (or kinds) of the communication module 1173 described above may be implemented as a single chip or as separate chips.

The input module 1130, the sensor module 1161, the camera module 1171, and/or the like may be used to control the operation of the display module 1140 in conjunction with the processor 1110.

The processor 1110 outputs commands or data to the display module 1140, the sound output module 1163, the camera module 1171, or the light module 1172, based on the input data received from the input module 1130. For example, the processor 1110 may generate image data in response to input data applied through a mouse or an active pen and output it to the display module 1140, or may generate command data in response to input data and output it to the camera module 1171 or the light module 1172. If the input data is not received from the input module 1130, the processor 1110 may reduce the power consumed by the electronic device 1000 by switching an operating mode of the electronic device 1000 to a low power mode or a sleep mode.

The processor 1110 outputs a command or data to the display module 1140, the sound output module 1163, the camera module 1171, or the light module 1172, based on sensing data received from the sensor module 1161. For example, the processor 1110 may compare authentication data applied by the fingerprint sensor 1161-1 with authentication data stored in the memory 1120, and then execute an application according to a comparison result. The processor 1110 may execute a command based on the sensing data detected by the input sensor 1161-2 or the digitizer 1161-3 or output corresponding image data to the display module 1140. If a temperature sensor is included in the sensor module 1161, the processor 1110 may receive temperature data of a measured temperature from the sensor module 1161, and further perform luminance correction on the image data based on the temperature data.

The processor 1110 may receive from camera module 1171 measurement data relating to the presence or absence of the user, the user's location, the user's line of sight and/or the line. The processor 1110 may further perform luminance correction on the image data based on the measurement data. For example, the processor 1110 which determines the presence or absence of the user through the input from the camera module 1171 may output the luminance-corrected image data to the display module 1140 through the data conversion circuit 1112-2 or the gamma correction circuit 1112-3.

Some of the components may be connected to each other using a communication scheme between peripherals, for example, a bus, general purpose input/output (GPIO), serial peripheral interface (SPI), mobile industry processor interface (MIPI), or ultra path interconnect (UPI) link to exchange a signal (e.g., a command or data) with each other. The processor 1110 may communicate with the display module 1140 in a mutually agreed interface, and may use, for example, any one of the above-described communication schemes, which is not limited to the above-described communication schemes.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity i.e., the limitations of the measurement system. For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between and including the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light emitting device, electronic apparatus, manufacturing devices for the light emitting device, or any other relevant devices or components according to embodiments of the present disclosure described herein may be implemented utilizing any suitable hardware, firmware (e.g., an application-specific integrated circuit, software, or a combination of software, firmware, and hardware). For example, the various components of the device may be formed on one integrated circuit IC chip or on separate IC chips. Further, the various components of the device may be implemented on a flexible printed circuit film, a tape carrier package TCP, a printed circuit board PCB, or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory RAM. The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display comprising pixels connected to a first power line, a second power line, scanning lines, and data lines;
a current sensor to sense a global current value flowing to the pixels;
a power generator to supply a first driving power to the first power line and a second driving power to the second power line; and
a timing controller to compare a limit current value corresponding to an upper limit value of a driving current flowing to the pixels with the global current value, and to control the power generator in response to a result of the comparison,
wherein the limit current value is set differently based on image refresh rates of the display.

2. The display device according to claim 1, wherein the higher an image refresh rate of the image refresh rates, the lower the limit current value is set in response to a specific load of the pixels.

3. The display device according to claim 1, wherein the timing controller is to control the power generator to lower a voltage of the first driving power if the global current value is above the limit current value.

4. The display device according to claim 1, further comprising:
a sensing resistor between the first power line and the display,
wherein the current sensor is connected to the sensing resistor to sense the global current value.

5. The display device according to claim 1, wherein the timing controller comprises:
a storage in which a plurality of limit current values corresponding to the image refresh rates are stored, the plurality of limit current values including the limit current value;
a frequency determiner to determine a current image refresh rate of the image refresh rates;
a selector to select a specific limit current value of the plurality of limit current values corresponding to the current image refresh rate from the storage; and
a power controller to control a voltage of the first driving power in response to a comparison result of the global current value and the specific limit current value.

6. The display device according to claim 5, wherein the frequency determiner is to receive a vertical synchronization signal, calculate one horizontal period in response to the vertical synchronization signal, and generate a horizontal period signal comprising information on the one horizontal period.

7. The display device according to claim 6, wherein the selector is to select the specific limit current value corresponding to the horizontal period signal and supply it to the power controller.

8. The display device according to claim 5, wherein the power controller is to generate a warning signal if the global current value is above the specific limit current value.

9. The display device according to claim 8, wherein the timing controller further comprises:
an analyzer to generate a load and a peak grayscale of input data; and
a code value generator to generate a voltage code to control the voltage of the first driving power in response to the load and the peak grayscale and to supply the voltage code to the power generator.

10. The display device according to claim 9, wherein the code value generator is to generate the voltage code to lower the voltage of the first driving power if the warning signal is inputted.

11. The display device according to claim 10, wherein the code value generator is to generate the voltage code to lower the voltage of the first driving power in a range for maintaining light-emitting state of the pixels if the warning signal is inputted.

12. The display device according to claim 9, wherein the power controller is to compare the global current value corresponding to the load with the specific limit current value.

13. A method of driving a display device, the method comprising:
detecting a global current value corresponding to a driving current flowing to pixels;
comparing the global current value with a limit current value corresponding to an upper limit value of the driving current in a power controller; and
controlling a voltage of a first driving power which supplies the driving current to the pixels in response to a result of the comparison of the global current value and the limit current value,
wherein the limit current value is set differently based on image refresh rates of the display.

14. The method according to claim 13, wherein the higher an image refresh rate of the image refresh rates, the lower the limit current value is set in response to a specific load of the pixels.

15. The method according to claim 13, wherein the voltage of the first driving power is lowered if the global current value is above the limit current value.

16. The method according to claim 15, wherein the lowered voltage of the first driving power is set to allow the pixels to maintain light emission.

17. The method according to claim 15, further comprising:
calculating one horizontal period utilizing a vertical synchronization signal;
determining an image refresh rate of the image refresh rates for driving the display device in response to the one horizontal period; and
selecting the limit current value corresponding to the image refresh rate and supplying the limit current value to the power controller.

18. An electronic device comprising:
a display panel comprising pixels, wherein the pixels are to receive a driving current from a first driving power;
a voltage generation circuit to generate the first driving power; and
a controller to compare a global current value corresponding to the driving current flowing to the pixels with a limit current value, and to control the voltage generation circuit in response to a result of the comparison,
wherein the limit current value is set differently for each image refresh rate of the display panel.

19. The electronic device according to claim 18, wherein the higher the image refresh rate, the lower the limit current value is set in response to a specific load of the pixels.

20. The electronic device according to claim 18, wherein the controller is to control the voltage generation circuit to lower a voltage of the first driving power if the global current value is above the limit current value.
